(19) United States
(12) Patent Application Publication
(10) Pub. No.: US 2015/0093883 A1
(43) Pub. Date: Apr. 2, 2015

(54) MANUFACTURING APPARATUS FOR SEMICONDUCTOR DEVICE AND MANUFACTURING METHOD FOR SEMICONDUCTOR DEVICE

(71) Applicant: NuFlare Technology, Inc., Kanagawa (JP)

(72) Inventors: Yoshikazu MORIYAMA, Shizuoka (JP); Shigeaki ISHII, Kanagawa (JP)

(21) Appl. No.: 14/501,864

(22) Filed: Sep. 30, 2014

(30) Foreign Application Priority Data
Oct. 2, 2013 (JP) 2013-207430

(51) Int. Cl. H01L 21/67; C23C 16/455; C23C 16/458; C23C 16/46; H01L 21/687; H01L 21/02

(52) U.S. Cl. CPC H01L 21/67017; H01L 21/68714; H01L 21/0262; H01L 21/02271; C23C 16/4584; C23C 16/46; C23C 16/455
USPC 438/478; 118/725

(57) ABSTRACT

According to a manufacturing apparatus for semiconductor device according to an embodiment of the present invention, a reaction chamber includes a gas introduction unit and a deposition reaction unit. The gas introduction unit includes a gas introduction port for introducing process gas and a buffer unit into which the process gas is introduced from the gas introduction port. In the deposition reaction unit, deposition reaction is performed on a wafer by the process gas. A rectifying plate provided under an area at least a part of which is enclosed by the buffer unit supplies the process gas introduced from a side of the buffer unit in a horizontally dispersed state to an upper surface of the wafer in a rectified state.

### CROSS-REFERENCE TO RELATED APPLICATIONS

This application is based upon and claims the benefit of priority from Japan Patent Application No. 2013-207430, filed on Oct. 2, 2013, the entire contents of which are incorporated herein by reference.

### FIELD

Embodiments described herein relate generally to a manufacturing apparatus for semiconductor device and a manufacturing method for semiconductor device.

### BACKGROUND

In general, in a semiconductor manufacturing process, a manufacturing apparatus for semiconductor device such as a CVD (chemical vapor deposition) device is used for forming a coating film such as an epitaxial film on a wafer surface. The CVD device forms the coating film on the wafer surface by placing a wafer on a susceptor, supplying process gas from above the wafer in a rectified state by using a rectifying plate, and rotating the same while heating, for example.

In a conventional manufacturing apparatus for semiconductor device, a diameter of the device is sufficiently large relative to the rectifying plate and a distance between a gas introduction port and the rectifying plate is long. Therefore, there is not a problem that pressure of the process gas supplied from the rectifying plate to an upper surface of the wafer significantly changes according to the distance from the gas introduction port to a discharge hole of the rectifying plate.

However, in a recent manufacturing apparatus for semiconductor device, it is required to (1) form the coating film having a uniform thickness by using a small amount of gas, (2) make a dead space of a spatial area in which deposition reaction is performed small and inhibit generation of a whirl within the area, and (3) make a gap between a rotation unit and a side wall of a reaction chamber small, thereby making the device small in order to inhibit deposition of a reaction by-product in the reaction chamber. When the diameter of the device is decreased, a gap between the gas introduction port and the rectifying plate is also made small. Thus, the closer the discharge hole is to the gas introduction port, the higher the pressure of the process gas supplied from the rectifying plate to the upper surface of the wafer is. Therefore, it is not possible to uniformly supply the process gas to the upper surface of the wafer. Such uniformity of the process gas may be improved by change in gas flow amount condition. However, it requires a large amount of process gas and this is contrary to an object to realize the small device.

### BRIEF DESCRIPTION OF THE DRAWINGS

FIG. 1 is a cross-sectional view of an entire configuration example of a reaction chamber of a manufacturing apparatus for semiconductor device according to a first embodiment;

FIG. 2 is a top view of a configuration example of a rectifying plate and a buffer unit. illustrated in FIG. 1:

FIG. 3 is a perspective view of a substantial part A indicated by a broken line in FIG. 2;

FIG. 4 is a cross-sectional view of an entire configuration example of a reaction chamber of a first variation of the first embodiment;

FIG. 5 is a top view of a configuration example of a rectifying plate and a buffer unit of a second variation of the first embodiment;

FIG. 6 is a cross-sectional view of an entire configuration example of a reaction chamber of a manufacturing apparatus for semiconductor device according to a second embodiment;

FIG. 7 is a top view of a configuration example of a rectifying plate, a buffer unit, and a weir member illustrated in FIG. 6;

FIG. 8 is a perspective view of a substantial part B indicated by a broken line in FIG. 7;

FIG. 9 is a front perspective view of a shape of a weir member of a first variation of the second embodiment;

FIG. 10 is a top view of shapes of a buffer unit and a weir member of a second variation of the second embodiment;

FIG. 11 is a top view of shapes of a buffer unit and a weir member of a third variation of the second embodiment; and

FIG. 12 is a top view of shapes of a buffer unit and a weir member of a fourth variation of the second embodiment.

### DETAILED DESCRIPTION

An embodiment of the present invention is hereinafter described in detail with reference to the drawings. Meanwhile, a case in which a φ200 mm wafer w made of silicon is used in a reaction chamber 10 is described as an example in each embodiment; however, a type of the wafer w to be used is not limited thereto.

### First Embodiment

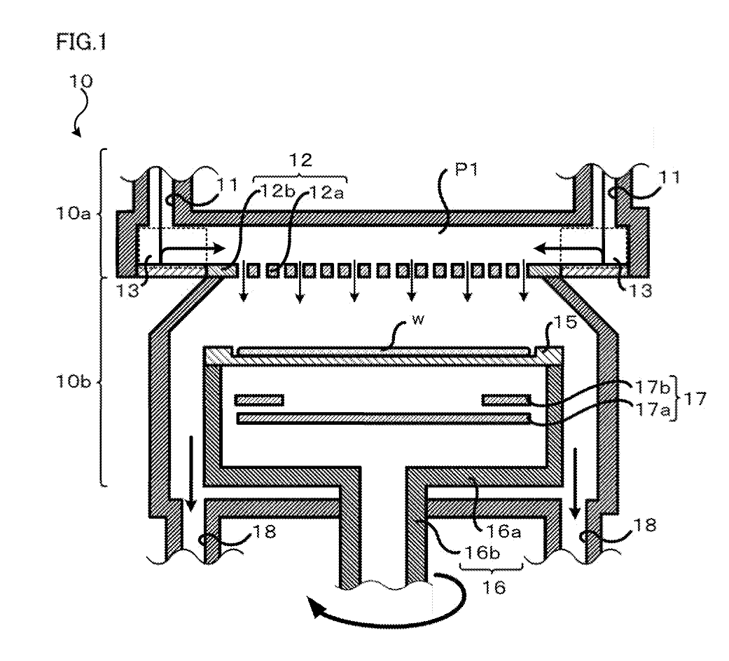

FIG. 1 is a cross-sectional view of an entire configuration example of a reaction chamber 10 of a manufacturing apparatus for semiconductor device according to this embodiment. As illustrated in the drawing, the reaction chamber 10 is formed of a gas introduction unit 10a and a deposition reaction unit 10b. In the gas introduction unit 10a, process gas including source gas (for example, trichlorosilane (SiHCl₃)), dichlorosilane (SiH₂Cl₂) and the like) and carrier gas (for example, hydrogen (H₂) and the like) is introduced. The deposition reaction unit 10b is provided under the gas introduction unit 10a. In the deposition reaction unit 10b, deposition reaction by the process gas is performed on an upper surface of a wafer w introduced into the deposition reaction unit 10b. In the gas introduction unit 10a, gas introduction ports 11 are provided in two places, for example, in the vicinity of an end of a ceiling surface thereof. The gas introduction port 11 is connected to a gas supply mechanism (not illustrated) for supplying the process gas. A buffer unit 13 for relaxing a process gas flow from the gas introduction port 11 is provided on the gas introduction unit 10a, the buffer unit is arranged so as to be opposed to the gas introduction port 11.

A rectifying plate 12 formed of a gas discharge unit 12a and a rectifying plate outer periphery 12b is provided between the gas introduction unit 10a and the deposition reaction unit 10b. A large number of discharge holes are formed on the gas discharge unit 12a for supplying the gas, the gas flow of which is weakened by the buffer unit 13, introduced into an area (P1 area) at least a part of which is enclosed by the buffer unit 13 into the deposition reaction unit 10b in a rectified state.

A susceptor 15 which is a type of a wafer supporting member for supporting the introduced wafer w is provided in the deposition reaction unit 10b. A rotation unit 16 formed of a rotation ring 16a in a cylindrical shape at the top of which the susceptor 15 is placed and a rotation axis 16b thereof is provided in the deposition reaction unit 10b. The rotation axis 16b of the rotation unit 16 is extended outside the reaction chamber 10 to be connected to a rotation drive control mechanism (not illustrated). The rotation drive control mechanism rotates the rotation unit 16 by driving force of a motor (not illustrated) and rotates the wafer w together with the susceptor 15 at 900 rpm, for example.

A heater 17 which heats the wafer w from a lower surface side is provided in the rotation unit 16. The heater 17 is formed of an in-heater 17a and an out-heater 17b. The in-heater 17a heats the wafer w from a central side. In contrast, the out-heater 17b provided between the in-heater 17a and the susceptor 15 heats the wafer w from an outer peripheral side. A disk-shaped reflector (not illustrated) may be arranged in a lower part of the in-heater 17a for efficiently heating the wafer w.

The in-heater 17a and the out-heater 17b are connected to a temperature control mechanism (not illustrated). The temperature control mechanism (not illustrated) heats through the wafer w such that in-plane temperature of the wafer w uniformly reaches 1,100 degrees C, for example, by appropriately adjusting an output such that temperature of the in-heater 17a and that of the out-heater 17b are within a range from 1,400 to 1,500 degrees C., for example, based on the in-plane temperature of the wafer w measured by a temperature measuring device (not illustrated).

Gas discharge ports 18 are provided in two places, for example, at the bottom of the reaction chamber 10. The gas discharge port 18 is connected to a gas discharge mechanism (not illustrated). The gas discharge mechanism includes a valve and a vacuum pump. The gas discharge mechanism discharges exhaust gas including the process gas left over after being supplied onto the wafer w and a reaction by-product from the reaction chamber 10 and controls pressure in the reaction chamber 10. The pressure in the reaction chamber 10 is adjusted by flow amounts of gas supply from the gas introduction port 11 and exhaust from the gas discharge port 18.

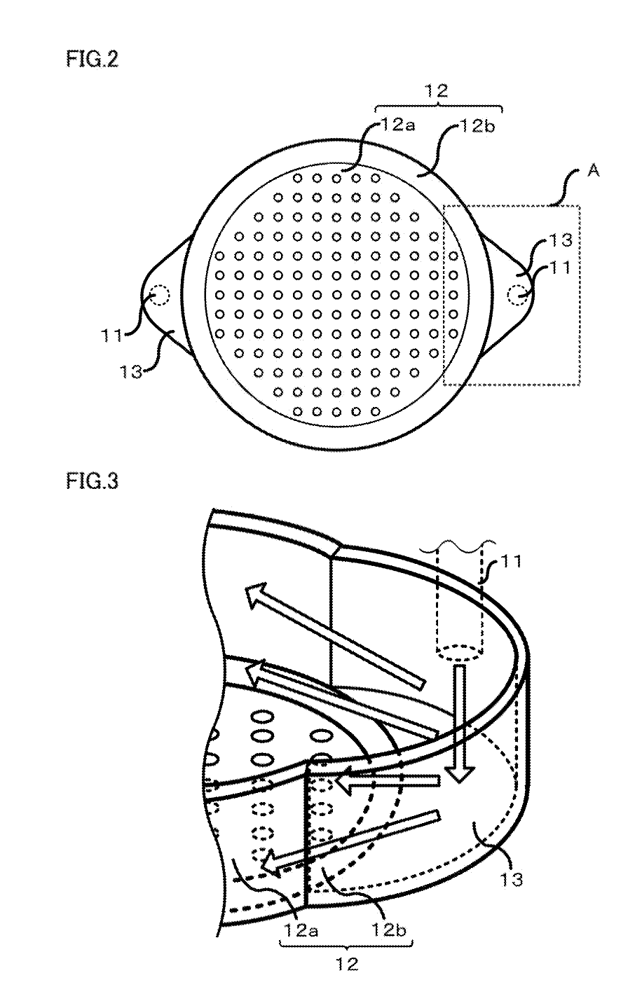

FIG. 2 is a top view of a configuration example of the rectifying plate 12 and the buffer unit 13 illustrated in FIG. 1. FIG. 3 is a perspective view of a substantial part A indicated by a broken line in FIG. 2. Herein, the buffer units 13 having a fun-shaped bottom surface are provided in two places on an outer side of the rectifying plate outer periphery 12b in a ring shape corresponding to the number and positions of the gas introduction ports 11. An arrow in FIG. 3 indicates an example of a direction in which the process gas introduced from the gas introduction port 11 into the buffer unit 13 moves. Meanwhile, the buffer unit 13 does not necessarily have the fan-shaped bottom surface and a size thereof may also be optionally changed.

Subsequently, a specific example of a method of forming a Si epitaxial film on the φ200 mm wafer w, for example, by using the manufacturing apparatus for semiconductor device configured in the above-described manner is described.

First, a gate (not illustrated) of the reaction chamber 10 is opened and the wafer w is carried into the reaction chamber 10 heated to 700 degrees C, for example, by a robot hand (not illustrated).

Next, a push-up mechanism (not illustrated) is raised, the wafer w is placed onto the push-up mechanism, the robot hand (not illustrated) is carried out of the reaction chamber 10, and the gate (not illustrated) is closed.

Next, the push-up mechanism is lowered to place the wafer w on the susceptor 15. Then, the temperature control mechanism (not illustrated) controls the in-heater 17a and the out-heater 17b to approximately 1,400 degrees C and 1,500 degrees C, respectively, such that the in-plane temperature of the wafer w uniformly reaches 1,100 degrees C, for example.

Then, a rotation drive mechanism (not illustrated) rotates the wafer w at 900 rpm, for example, and the process gas (for example, carrier gas: 61 slm of H₂ and source gas: 16.5 slm of SiHCl₃ at an approximately 20% concentration mixed with H₂) is introduced from the gas introduction port 11, and the pressure in the reaction chamber 10 is adjusted to 700 Torr.

The process gas introduced from the gas introduction port 11 is first supplied into the buffer unit 13 to be temporarily received by the buffer unit 13. Thus, the process gas moves from the buffer unit 13 toward the gas discharge unit 12a of the rectifying plate 12 so as to be dispersed in a horizontal direction as illustrated in FIG. 3. As a result, the process gas is supplied onto the wafer w in the rectified state through the rectifying plate 12 and a flow amount thereof is constant regardless of a position of the discharge hole on the gas discharge unit 12a.

The gas such as the left over process gas including SiHCl₃, diluent gas, HCl being the reaction by-product is discharged from the gas discharge port 18 and the pressure in the reaction chamber 10 is controlled to be constant. In this manner, each condition is controlled and the Si epitaxial film is grown on the wafer w.

As described above, according to the manufacturing apparatus for semiconductor device according to this embodiment, it is possible to introduce the process gas into the buffer unit 13 provided on the outer side of the rectifying plate 12 and efficiently spread the same on the rectifying plate 12 by partially providing a desired size of buffer unit 13 on the outer side of the rectifying plate 12 on a side of the gas introduction unit 10a while making a diameter of the reaction chamber 10 significantly smaller than that of a conventional type. Therefore, it is possible to make the flow amount of the process gas supplied from the rectifying plate 12 to the upper surface of the wafer w constant regardless of the position of the discharge hole. As a result, it is possible to improve uniformity of a film thickness.

Meanwhile, the invention is not limited to this embodiment and this may be carried out with various variations within the scope of the spirit thereof.

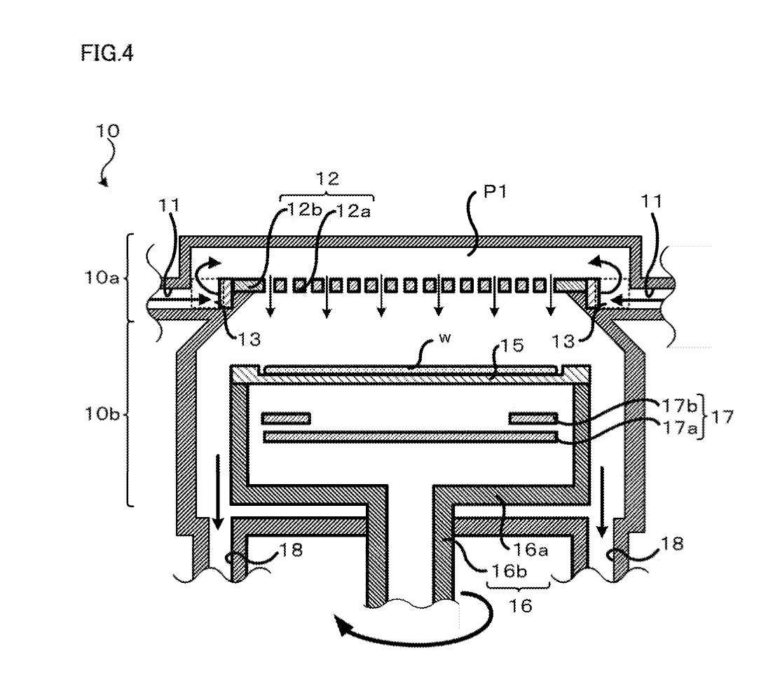

For example, it is also possible to form the gas introduction port 11 on a side surface of the reaction chamber 10 to supply the process gas not in a vertical downward direction but in the horizontal direction as illustrated in a cross-sectional view in FIG. 4. That is to say, it is not necessarily required that the gas introduction port 11 be provided on the ceiling surface of the reaction chamber 10 and a direction in which the process gas is supplied may be not only the vertical downward direction but also the horizontal direction.

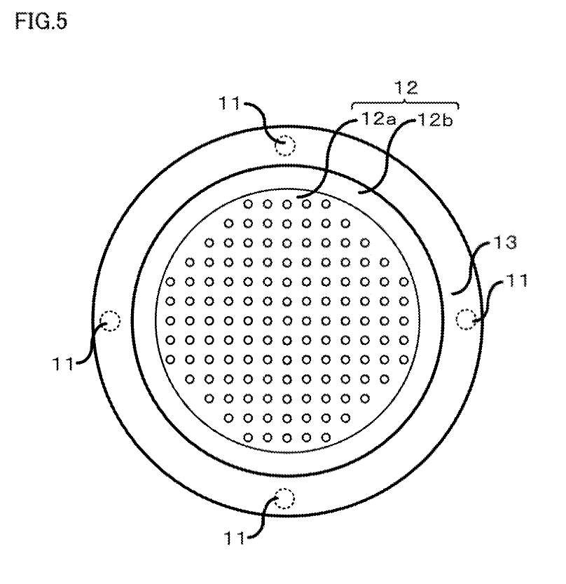

As illustrated in a top view in FIG. 5, it is also possible to arrange the buffer unit 13 having a ring-shaped bottom surface so as to enclose an entire periphery of an area over the rectifying plate 12 instead of partially arranging the buffer unit 13 having the fan-shaped bottom surface on the outer side of the rectifying plate 12.

### Second Embodiment

A second embodiment of the present invention is hereinafter described. Meanwhile, since a reference sign common to that assigned in the above-described first embodiment represents a same target, the description thereof is omitted; a portion different from that of the first embodiment is hereinafter described in detail.

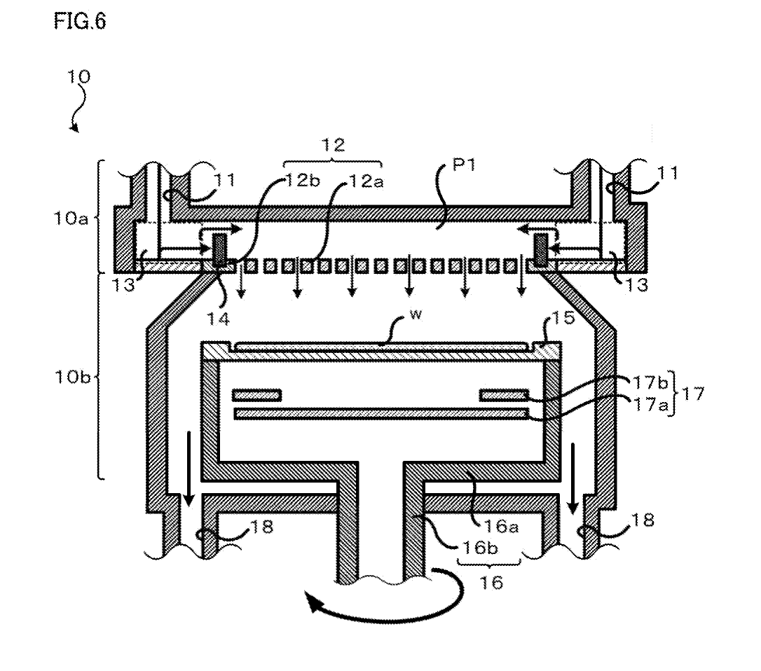

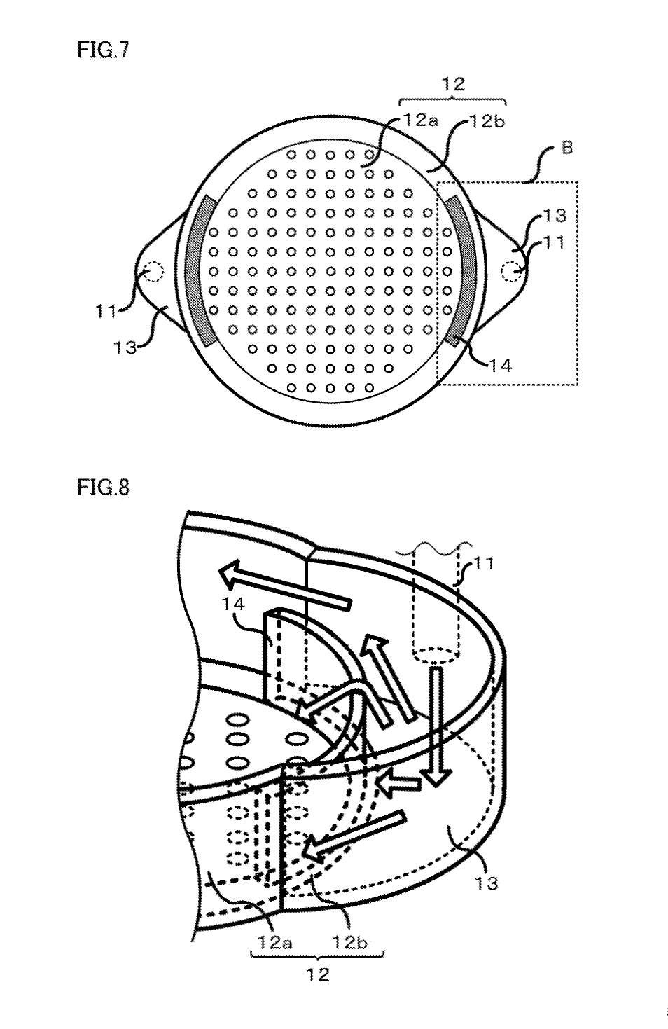

FIG. 6 is a cross-sectional view of an entire configuration example of a reaction chamber 10 of a manufacturing apparatus for semiconductor device according to the second embodiment. FIG. 7 is a top view of a configuration example of a rectifying plate 12, a buffer unit 13, and a weir member 14 illustrated in FIG. 6. FIG. 8 is a perspective view of a substantial part B indicated by a broken line in FIG. 7. As illustrated in the drawings, the manufacturing apparatus for semiconductor device according to this embodiment is different from that of the first embodiment in that the weir member 14 is further provided. The weir member 14 is formed between the buffer unit 13 and the rectifying plate 12 so as to protrude upward as a barrier of a flow of process gas introduced from the buffer unit 13 to the rectifying plate 12.

The weir member 14 is formed on a rectifying plate outer periphery 12b being an area provided between the buffer unit 13 and a gas discharge unit 12a of the rectifying plate 12 so as to protrude at a predetermined height in a direction toward a ceiling surface of the reaction chamber 10. A width in a longitudinal direction of the weir member 14 is adjusted so as to be at least wider than a width of the buffer unit 13. It is preferable to attachably/detachably form the weir member 14 in order to change the height, a thickness, or the width thereof according to a deposition condition.

The manufacturing apparatus for semiconductor device according to this embodiment changes a shape in the middle of a flow channel of the process gas by providing the weir member 14. The flow channel of the process gas in a case in FIGS. 6 to 8 is as follows.

For example, the process gas (for example, carrier gas: 61 slm of H₂ and source gas: 16.5 slm of SiHCl₃ at an approximately 20% concentration mixed with H₂) is introduced from a gas introduction port 11 to the buffer unit 13 such that pressure in the reaction chamber 10 is adjusted to 700 Torr.

Next, the process gas introduced into the buffer unit 13 is received by the buffer unit 13 to move so as to be dispersed in a horizontal direction. Thereafter, when the process gas collides with the weir member 14, this bypasses the weir member 14 while passing above the same or on right and left sides thereof as illustrated in FIG. 8. In a place in which the weir member 14 is provided corresponding to a position of the buffer unit 13, the gas flow of the process gas from above downward on the rectifying plate 12 is formed. In contrast, in a place in which the weir member 14 is not provided, the gas flow in the horizontal direction bypassing the weir member 14 while passing on the right and left sides thereof is formed. As a result, it is possible to significantly change a direction of the gas flow by positional relationship between a discharge hole formed on the rectifying plate 12 and the weir member 14.

As described above, according to the manufacturing apparatus for semiconductor device according to this embodiment, it is possible to suppress a supply amount of the process gas in the vicinity of the gas introduction port and make the gas amount supplied to the rectifying plate uniform in all the discharge holes by providing the weir member 14. As a result, it is possible to improve uniformity of a film thickness.

Meanwhile, the invention is not limited to this embodiment and this may be carried out with various variations within the scope of the spirit thereof.

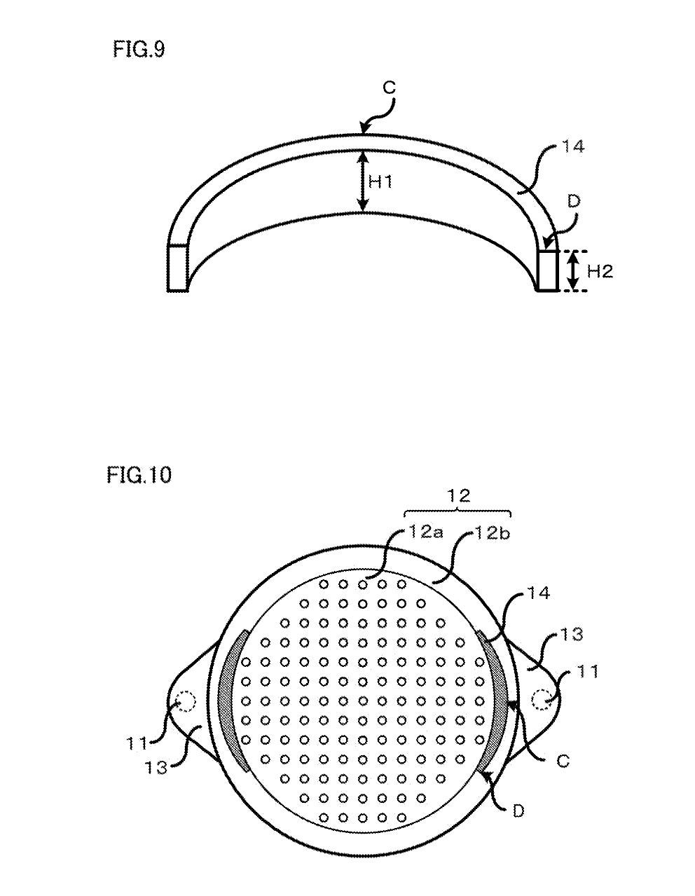

As illustrated in a front perspective view in FIG. 9, the height of the weir member 14 may be made such that height H1 in point C in a central portion is higher than height H2 in point Don an end. Furthermore, as illustrated in a top view of a shape of the weir member 14 in FIG. 10, it is also possible to adjust the thickness in point C in the central portion so as to be thicker than that in point D on the end. It is possible to suppress the supply amount of the process gas in the vicinity of the gas introduction port 11 and make the gas amount supplied to the rectifying plate 12 uniform in all the discharge holes by configurations illustrated in FIGS. 9 and 10. Meanwhile, although the height and the thickness of the weir member 14 are partially adjusted in FIGS. 9 and 10, it is also possible to similarly adjust the same totally.

Similarly, as illustrated in a top view in FIG. 11, it is also possible to form the weir member 14 such that the width thereof is significantly wider than the width of the buffer unit 13. Meanwhile, it is preferable that the height, the thickness, and the width of the weir member 14 are optionally adjusted based on the position and a size of the buffer unit 13, a flow amount condition of the process gas and the like to be optimized through an experiment and the like. It becomes possible to control a growth condit ion of a Si epitaxial film on a wafer w in further detail by changing the height, the thickness, or the width of the weir member 14.

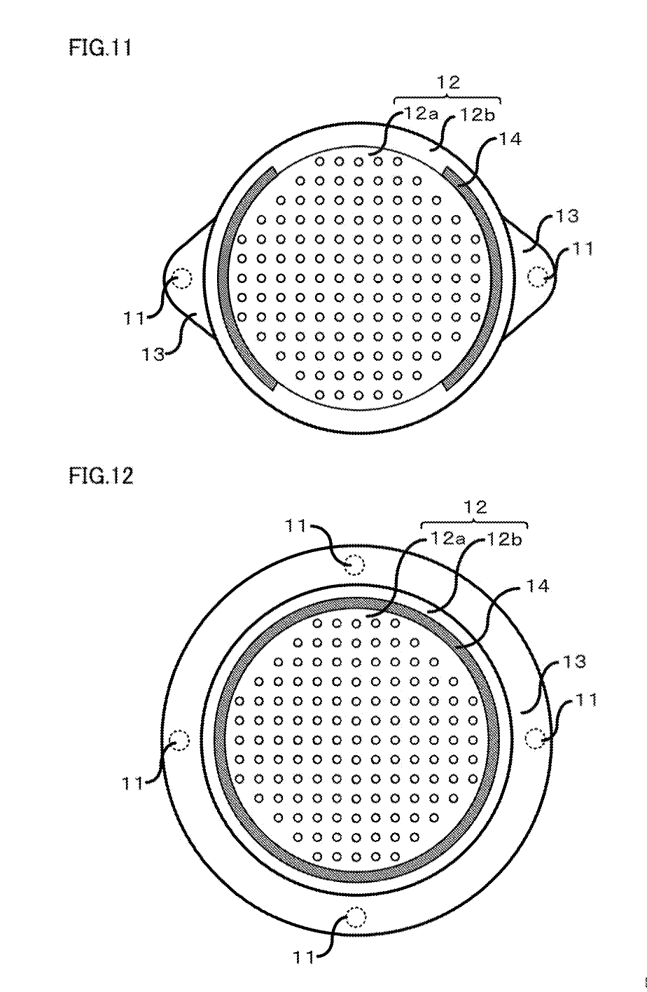

It is also possible to arrange the buffer unit 13 in a ring shape on an entire periphery of an area over the rectifying plate 12 and form the weir member 14 in a ring shape as illustrated in a top view in FIG. 12.

Although the weir member 14 is formed on the rectifying plate outer periphery 12b in the above-described second embodiment, it is only required that this be provided at least between the buffer unit 13 and the gas discharge unit 12a of the rectifying plate 12. Therefore, the weir member 14 may also be provided on a side of the buffer unit 13 so as to be adjacent to the rectifying plate outer periphery 12b.

In the above-described two embodiments, it is not necessarily required that a bottom surface of the buffer unit 13 be on a same horizontal plane as an upper surface of the rectifying plate 12 and the bottom surface of the buffer unit 13 may be arranged above or below the upper surface of the rectifying plate 12. That is to say, it is only required that the buffer unit 13 be an area capable of temporarily receiving the process gas supplied from the gas introduction port 11 and the position and the size thereof may be optionally determined according to positions of the gas introduction port 11 and the rectifying plate 12.

Furthermore, although formation of a single-layered Si epitaxial film is described as an example in the above-described embodiments, this may be applied to deposition of a GaN-based compound semiconductor, other insulating films such as a poly Si layer, a SiO₂ layer, and a Si₃N₄ layer, and a compound semiconductor such as SiC, GaAlAs, and InGaAs. This may also be applied when dopant of a semiconductor film is changed.

What is claimed is:

1. A manufacturing apparatus for semiconductor device comprising:
a reaction chamber provided with a gas introduction unit including a gas introduction port for introducing process gas and a buffer unit into which the process gas is introduced from the gas introduction port, and a deposition reaction unit in which deposition reaction is performed on a wafer by the process gas;
a rectifying plate provided under an area at least a part of which is enclosed by the buffer unit, and supplying the process gas introduced from a side of the buffer unit in a horizontally dispersed state to an upper surface of the wafer in a rectified state;
a wafer supporting member provided in the deposition reaction unit which supports the wafer;
a rotation unit provided in the deposition reaction unit which supports an outer periphery of the wafer supporting member to rotate the wafer together with the wafer supporting member;
a heater provided in the rotation unit which heats the wafer from a lower surface side; and
a gas discharge port provided at the bottom of the reaction chamber which discharges exhaust gas including a reaction by-product in the deposition reaction.

2. The manufacturing apparatus for semiconductor device according to claim 1, wherein the buffer unit is arranged so as to be opposed to the gas introduction port.

3. The manufacturing apparatus for semiconductor device according to claim 2, wherein the buffer unit is arranged in a horizontal direction when the process gas is supplied from the gas introduction port in a vertical downward direction.

4. The manufacturing apparatus for semiconductor device according to claim 2, wherein the buffer unit is arranged in a vertical direction when the process gas is supplied from the gas introduction port in a horizontal direction.

5. The manufacturing apparatus for semiconductor device according to claim 2, wherein the buffer unit is partially arranged in an outer peripheral area over the rectifying plate.

6. The manufacturing apparatus for semiconductor device according to claim 2, wherein the buffer unit is formed into a ring shape and is arranged so as to enclose an area over the rectifying plate.

7. The manufacturing apparatus for semiconductor device according to claim 1, further comprising: a weir member formed between the buffer unit and the rectifying plate so as to protrude upward as a barrier of a flow of the process gas introduced from the buffer unit to the rectifying plate.

8. The manufacturing apparatus for semiconductor device according to claim 7, wherein the buffer unit is arranged so as to be opposed to the gas introduction port.

9. The manufacturing apparatus for semiconductor device according to claim 8, wherein the weir member is partially arranged in an outer peripheral area over the rectifying plate corresponding to the number and a position of the buffer unit.

10. The manufacturing apparatus for semiconductor device according to claim 9, wherein a height, a thickness, and a width of the weir member are adjusted based on the position and a size of the buffer unit and a flow amount condition of the process gas.

11. The manufacturing apparatus for semiconductor device according to claim 10, wherein the height of the weir member is adjusted so as to be lower with distance from the gas introduction port.

12. The manufacturing apparatus for semiconductor device according to claim 10, wherein the thickness of the weir member is adjusted so as to be thinner with distance from the gas introduction port.

13. The manufacturing apparatus for semiconductor device according to claim 10, wherein the width of the weir member is adjusted so as to be wider than a width of the buffer unit.

14. The manufacturing apparatus for semiconductor device according to claim 10, wherein the weir member is formed into a ring shape and arranged so as to enclose an area over the rectifying plate.

15. The manufacturing apparatus for semiconductor device according to claim 10, wherein the weir member is attachable and detachable.

16. A manufacturing method for semiconductor device comprising:
loading a wafer into a reaction chamber to support;
introducing process gas into a buffer unit formed in an inner spatial area in an upper part of the reaction chamber;
introducing the process gas from the buffer unit into an area over a rectifying plate at least a part of which is enclosed by the buffer unit in a horizontally dispersed state;
supplying the process gas to an upper surface of the wafer in a rectified state through the rectifying plate; and
rotating the wafer while heating the wafer from below to deposit a film on the upper surface of the wafer.

17. The manufacturing method for semiconductor device according to claim 16, wherein the process gas is first supplied into the buffer unit to be temporarily received by the buffer unit.

18. The manufacturing method for semiconductor device according to claim 17, comprising: controlling a flow of the process gas introduced from the buffer unit to the rectifying plate by a weir member formed between the buffer unit and the rectifying plate so as to protrude upward.

19. The manufacturing method for semiconductor device according to claim 18, wherein a height, a thickness, and a width of the weir member are adjusted based on a position and a size of the buffer unit and a flow amount condition of the process gas.

20. The manufacturing method for semiconductor device according to claim 18, comprising: adjusting a height, a thickness, and a width of the weir member by attaching/detaching the weir member.
